(19) United States
(12) Patent Application Publication
(10) Pub. No.: US 2026/0202977 A1
(43) Pub. Date: Jul. 16, 2026

(54) REFRESH CONTROL CIRCUIT, MEMORY, AND REFRESH CONTROL METHOD

(71) Applicant: CXMT Corporation, Hefei City (CN)

(72) Inventors: Xiaojie ZHAO, Hefei City (CN); Xudong WANG, Hefei City (CN); Runfa ZHOU, Hefei City (CN); Hao WU, Hefei City (CN); Yinchuan GU, Hefei City (CN)

(73) Assignee: CXMT Corporation, Hefei City (CN)

(21) Appl. No.: 19/428,111

(22) Filed: Dec. 20, 2025

Related U.S. Application Data
(63) Continuation of application No. PCT/CN2025/132849, filed on Nov. 5, 2025.

(30) Foreign Application Priority Data
Jan. 2, 2025 (CN) 202510007643.7

(51) Int. Cl. G06F 3/06

(52) U.S. Cl. CPC G06F 3/0632; G06F 3/0604; G06F 3/0673

(57) ABSTRACT

Provided a refresh control circuit, a memory, and a refresh control method. The refresh control circuit includes a page table, a first comparison circuit, and a second comparison circuit. The page table is configured to store a plurality of row addresses and their activation counts. The first comparison circuit is connected to the page table and is configured to receive a currently activated row address and its activation count, compare it with the plurality of row addresses and activation counts stored in the page table, and store the currently activated row address and its activation count into the page table when a first preset condition is met. The second comparison circuit is connected to the page table and is configured to compare the activation counts of the plurality of row addresses in the page table and output a row address with the maximum activation count as a candidate row address.

### CROSS-REFERENCE TO RELATED APPLICATIONS

This is a continuation of International Patent Application No. PCT/CN2025/132849 filed on November 5, 2025, which claims priority to Chinese Patent Application No. 202510007643.7 filed on January 2, 2025. The disclosures of the above-referenced applications are hereby incorporated by reference in their entirety.

### BACKGROUND

For a dynamic random access memory (DRAM), there is a hardware vulnerability known as Row Hammer (Row Hammer). When a row is accessed, due to the coupling effect, its adjacent rows are also subjected to certain electrical influence. When a particular row is frequently accessed (i.e., the so-called “hammered”), the charge in its adjacent rows may be incorrectly flipped, resulting in data corruption. This phenomenon is known as Row Hammer.

To address the Row Hammer problem, the industry has adopted various protective measures, for example, increasing refresh frequency, performing Target Row Refresh (Target Row Refresh, TRR), and using Error Correcting Code (Error Correcting Code, ECC) circuits. With the development of technology, a new technology known as Per-Row Activation Counting (Per-Row Activation Counting, PRAC) has emerged to precisely calculate DRAM activation counts at the row granularity. When the DRAM detects that the activation count of a row exceeds a threshold, it alerts the system to pause operations such as activation, read, and write, and to take mitigation measures at a specified time. The close coordination between the DRAM and the system provides a substantially accurate and predictable approach to addressing the data integrity challenges. However, there are more than 64K rows in the DRAM. Performing real-time monitoring on the activation counts for the 64K rows imposes a great burden on the operation of the memory, and the efficiency is low.

### SUMMARY

The present disclosure relates to the field of semiconductor technologies, and in particular, to a refresh control circuit, a memory, and a refresh control method, which can address the problem of heavy burden and low efficiency of the Row Hammer refresh solution on the memory in the current technology.

According to some embodiments of the present application, an aspect of the embodiments of the present application provides a refresh control circuit. The refresh control circuit includes a page table, a first comparison circuit, and a second comparison circuit. The page table is configured to store a plurality of row addresses and activation counts of the plurality of row addresses. The first comparison circuit is connected to the page table, and is configured to receive a currently activated row address and an activation count thereof, compare the currently activated row address and the activation count thereof with the plurality of row addresses and the activation counts thereof stored in the page table, and store, when a first preset condition is met, the currently activated row address and the activation count thereof into the page table. The second comparison circuit is connected to the page table, and is configured to compare the activation counts of the plurality of row addresses in the page table, and output a row address with a maximum activation count as a candidate row address.

In some embodiments, the refresh control circuit is configured to generate an Alert Back-off signal when a second preset condition is met. The Alert Back-off signal is a flag signal in a memory for pausing a read/write operation and performing a refresh operation.

In some embodiments, the second preset condition is that a minimum value among activation counts of all row addresses in the page table is greater than a preset threshold.

In some embodiments, the page table is configured to store, in a first time period, a row address output by the first comparison circuit and an activation count thereof; and the page table is further configured to store, in a second time period, a row address output by a third comparison circuit, and perform an operation of increment by 1 on a count value corresponding to the row address stored in the page table.

In some embodiments, the refresh control circuit is configured to periodically receive a refresh command, refresh, based on the refresh command, one or more rows adjacent to the candidate row address, and remove the candidate row address from the page table.

In some embodiments, the first preset condition includes: an available entry not storing a row address is present in the page table, the currently activated row address is the same as the row address stored in the page table, or the activation count of the currently

activated row address is greater than a minimum value among the activation counts of the plurality of row addresses stored in the page table.

According to some embodiments of the present application, another aspect of the embodiments of the present application further provides a memory. The memory includes the refresh control circuit according to any one of the foregoing embodiments and a bank. The bank includes a plurality of rows, and the plurality of rows store memory data and activation counts.

According to some embodiments of the present application, another aspect of the embodiments of the present application further provides a refresh control method. The refresh control method includes: determining whether a currently activated row address is the same as a row address stored in a page table; if the currently activated row address is the same as the row address stored in the page table, updating an activation count corresponding to the row address in the page table to an activation count carried by the currently activated row address; if the currently activated row address is not the same as the row address stored in the page table, comparing an activation count carried by the currently activated row address with a minimum value of an activation count in the page table, and determining whether the activation count carried by the currently activated row address is greater than the minimum value of the activation count in the page table; if the activation count carried by the currently activated row address is greater than the minimum value of the activation count in the page table, replacing a row address corresponding to the minimum value of the activation count in the page table and the activation count thereof with the currently activated row address and the activation count thereof; and if the activation count carried by the currently activated row address is less than the minimum value of the activation count in the page table, keeping data in the page table unchanged.

In some embodiments, the refresh control method further includes: comparing the minimum value of the activation count in the page table with a preset threshold, and generating an Alert Back-off signal if the minimum value of the activation count in the page table is greater than the preset threshold. The Alert Back-off signal is a flag signal in a memory for pausing a read/write operation and performing a refresh operation.

In some embodiments, the refresh control method further includes: refreshing one or more rows adjacent to a row address with a maximum activation count in the page table.

The technical solutions provided according to the embodiments of the present application at least have the following advantages:

### 0016] A refresh control circuit is provided. By storing the activated row address and the

activation count thereof in the page table, and comparing the currently activated row address and the activation count thereof with the row address and the activation count thereof stored in the page table each time, the row address that meets the condition can be selected according to a preset rule, thereby avoiding real-time monitoring and tracking of all rows in the memory, and thus reducing the monitoring burden of the memory. In addition, since the row address with the maximum activation count in the page table is output as the candidate row address, the adjacent rows thereof can be periodically refreshed, thereby reducing the frequency of pause of memory operation and improving the operating efficiency of the memory.

### BRIEF DESCRIPTION OF DRAWINGS

One or more embodiments are illustrated by images in corresponding drawings, and these exemplary explanations are not to be construed as limiting the embodiments. Unless expressly stated otherwise, the images in the drawings do not constitute a proportion limitation.

FIG. 1 is a schematic diagram of a bank according to an embodiment of the present disclosure;

FIG. 2 is a schematic diagram of a refresh control circuit according to an embodiment of the present disclosure;

FIG. 3 is a schematic diagram of a memory according to an embodiment of the present disclosure;

FIG. 4 is a flowchart of a refresh control method according to an embodiment of the present disclosure; and

FIG. 5 is a schematic diagram of a dynamic change of data in a page table according to an embodiment of the present disclosure.

### DESCRIPTION OF EMBODIMENTS

Exemplary embodiments of the present disclosure will be described in detail below with reference to the drawings, such that those skilled in the art can easily practice the present disclosure. As those skilled in the art will recognize, the described embodiments may be modified in various ways, all without departing from the spirit or scope of the present disclosure. For example, the exemplary embodiments provided herein are considered to be capable of being combined in whole or in part for implementation. Specifically, an element described in a particular exemplary embodiment, even if not described in another exemplary embodiment,

can be understood as a description relating to another exemplary embodiment, unless a contrary or contradictory description is provided therein.

Throughout this specification, when any part is referred to as being “connected” to another part, it includes the case where any part and another part are “indirectly connected” to each other with other parts interposed therebetween and the case where any part and another part are “directly connected” to each other. For example, it should be understood that when an element is referred to as being “connected” or “coupled” to another element, or “on” another element, it can be directly connected or coupled to another element or directly on another element, or an intervening element may be present. In contrast, when an element is referred to as being “directly connected” or “directly coupled” to another element, or “in contact with” another element, no intervening elements are present at the point of contact.

Furthermore, “electrically connected” conceptually includes being physically connected and being physically disconnected. It can be understood that when terms such as “first” and “second” are used to refer to an element, the element is not so limited. They may be used only for the purpose of distinguishing one element from another and may not limit the order or importance of the elements. In some cases, the first element may be termed the second element without departing from the scope of the claims set forth herein. Similarly, the second element may also be referred to as the first element.

As can be seen from the background, the Per-Row Activation Counting (PRAC) enables counting and storage of the activation count of each row, and monitoring and detection of the activation count of the row. When it is detected that the activation count of a row exceeds a threshold, the system is alerted to pause operations, such as activation, read, and write, and to take mitigation measures at a specified time. However, there are more than 64K rows in the DRAM. Performing detection on the activation counts for the 64K rows imposes a great burden on the operation of the memory. In addition, once it is detected that the activation count of a row exceeds a threshold, a pause operation is triggered, and the memory stops the current operations, such as activation, read, and write, which also reduces the operating efficiency of the memory.

Therefore, the present application provides a refresh control circuit. The refresh control circuit includes a page table, a first comparison circuit, and a second comparison circuit. The page table is configured to store a plurality of row addresses and activation counts of the plurality of row addresses. The first comparison circuit is connected to the page table, and is configured to receive a currently activated row address and a activation count thereof, compare the currently activated row address and the activation count thereof with the plurality of row

addresses and the activation counts thereof stored in the page table, and store, when a first preset condition is met, the currently activated row address and the activation count thereof into the page table. The second comparison circuit is connected to the page table, and is configured to compare the activation counts of the plurality of row addresses in the page table, and output a row address with the maximum activation count as a candidate row address. By storing the activated row address and the activation count thereof in the page table, and comparing the currently activated row address and the activation count thereof with the row address and the activation count thereof stored in the page table each time, the row address that meets the condition can be selected according to a preset rule, thereby avoiding real-time monitoring and tracking of all rows in the memory, and thus reducing the monitoring burden of the memory. In addition, since the row address with the maximum activation count in the page table is output as the candidate row address, the adjacent rows thereof can be periodically refreshed, thereby reducing the frequency of pause of memory operation and improving the operating efficiency of the memory.

Furthermore, the page table in the solutions of the present application is different from a conventional page table. The conventional page table essentially performs a probabilistic refresh, in which randomly sampled addresses are stored in the page table. This mechanism heavily depends on the randomness of sampling, the capacity of the page table, and the refresh frequency. However, in the present application, the currently activated row address and the activation count thereof are directly used, which can avoid the defect of random sampling and prevent omission. In addition, since the activation count is directly obtained, the accuracy is higher.

The embodiments of the present application will be described in detail below with reference to the drawings. Those of ordinary skill in the art can understand that, in the embodiments of the present application, numerous technical details are set forth in order to enable readers to better understand the present application. However, the technical solutions claimed by the present application can also be implemented even without these technical details and the various changes and modifications based on the following embodiments.

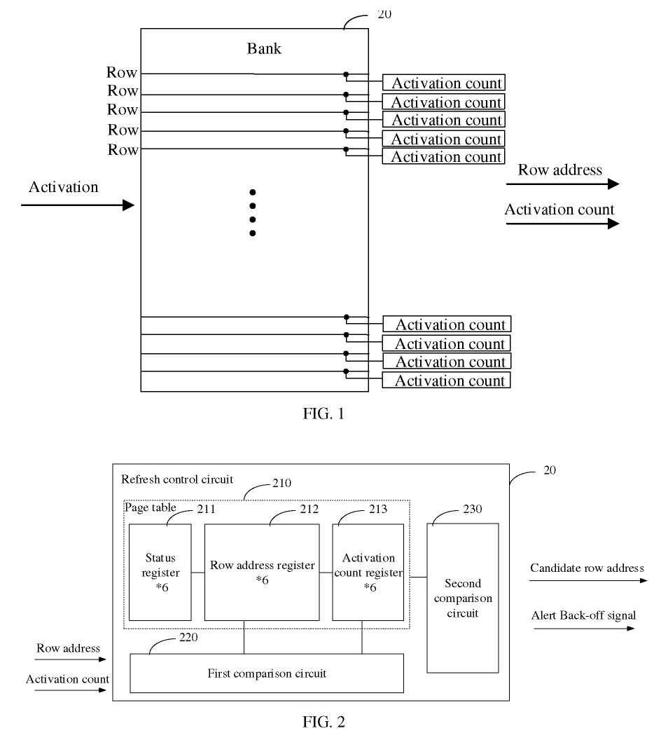

FIG. 1 is a schematic diagram of a bank according to an embodiment of the present application. A memory includes a plurality of banks, and each bank includes a plurality of memory cells arranged in rows and columns. One row of memory cells forms one row (row). Each row has a plurality of memory cells. A portion of memory cells stores memory data (memory data), and a portion of memory cells stores an activation count (Activation Count, AC) of the row. For each activation (ACT) operation, the memory can obtain the row address

of the activated row and the activation count of the activated row.

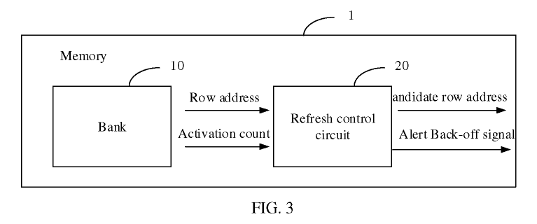

FIG. 2 is a schematic diagram of a refresh control circuit according to an embodiment of the present application. The refresh control circuit 20 includes a page table 210, a first comparison circuit 220, and a second comparison circuit 230.

The page table 210 is configured to store a plurality of row addresses and the activation counts of the plurality of row addresses.

The first comparison circuit 220 is connected to the page table 210, and is configured to receive a currently activated row address and the activation count thereof, compare the currently activated row address and the activation count thereof with the plurality of row addresses and the activation counts thereof stored in the page table, and store, when a first preset condition is met, the currently activated row address and the activation count thereof into the page table.

The second comparison circuit 230 is connected to the page table 210, and is configured to compare the activation counts of the plurality of row addresses in the page table 210, and output the row address with the maximum activation count as a candidate row address.

Specifically, in some embodiments, the page table may be formed by a structure having a storage function in the memory. For example, the page table may be a First In First Out (First In First Out, FIFO) register group. The First In First Out register group may be configured to store information. A group of First In First Out registers may include a status register 211, a row address register 212, and an activation count register 213, to form one row of the page table 210. The page table shown in FIG. 2 has six rows in total. Correspondingly, the First In First Out register group includes six groups of registers, and may store six row addresses and related information thereof. The information stored in the status register 211 is used to indicate whether a row address is stored in the row of the page table, that is, to indicate whether the row of the page table is occupied. The information stored in the row address register 212 is the row address information written into the page table. The information stored in the activation count register 213 is the activation count corresponding to the row address stored in the row. In some other embodiments, the activation count register 213 may alternatively be a counter. In yet some other embodiments, the page table may alternatively be formed by a portion of memory cells in the memory array.

The activation count of a row address refers to the number of times the row address is activated within one refresh period or one counting period. If the row is refreshed, the activation count is reset, and the calculation of activation counts is restarted.

Referring to FIG. 2, the first comparison circuit 220 receives a currently activated row address and the activation count thereof. With reference to FIG. 1, the currently activated row address is the row address of a memory cell corresponding to a current activation command, and the activation count of the currently activated row address is the activation count stored in the corresponding row in the memory array, which can be directly read from the row. Since the first comparison circuit 220 can directly receive the currently activated row address and the activation count thereof, additional processing logic can be omitted compared with other manners, such as random sampling. In addition, since the first comparison circuit 220 operates corresponding to the current row activation, a wider range of row addresses that may suffer from Row Hammer can be covered, thereby preventing omission.

The first comparison circuit 220 is further connected to the page table 210. The first comparison circuit compares the currently activated row address and the activation count thereof with a plurality of row addresses and the activation counts thereof stored in the page table, and stores, when a first preset condition is met, the currently activated row address and the activation count thereof into the row address register and the activation count register of the page table. In some embodiments, if the row address to be written into the page table is already stored in the page table, the activation count may be written only to the activation count register of the page table.

The first comparison circuit may be formed using a comparator. The comparator may be configured to compare each row address stored in the row address register 212 with the currently activated row address to determine whether they are the same. Alternatively, the comparator may be configured to compare the activation count of each row address stored in the activation count register 213 with the activation count of the currently activated row address to determine their relative magnitudes. Alternatively, the comparator may be configured to compare the minimum value among the activation counts of all row addresses stored in the activation count register 213 with the activation count of the currently activated row address, to determine the magnitude between the minimum value and the activation count of the currently activated row address. Through the comparison by the first comparison circuit, the operation complexity of monitoring at least 64K rows can be reduced.

The second comparison circuit 230 may be formed using a comparator. The second comparison circuit 230 is connected to the page table 210. The second comparison circuit compares the activation counts of a plurality of or all row addresses in the page table 210, and outputs the row address with the maximum activation count as the candidate row address. Specifically, the second comparison circuit 230 is connected to the row address register 212 and the activation count register 213. The second comparison circuit compares a plurality of or all activation counts stored in the activation count register 213, and outputs the row address with the maximum activation count as the candidate row address.

During the operation of the refresh control circuit, each time the row address stored in the page table changes, both the first comparison circuit and the second comparison circuit change accordingly. The row address corresponding to the minimum value among the activation counts pointed to by the first comparison circuit may change, and the row address corresponding to the maximum value among the activation counts pointed to by the second comparison circuit may also change.

Since the second comparison circuit 230 identifies the row address with the maximum activation count through comparison, the refresh control circuit can take the row address with the maximum activation count in the page table as a Row Hammer address for periodic refresh, thereby reducing the number of times triggering pause operation and improving the system defense performance.

In this way, by storing the activated row address and the activation count thereof in the page table, and comparing the currently activated row address and the activation count thereof with the row address and the activation count thereof stored in the page table each time, the row address that meets the condition can be selected according to a preset rule, thereby avoiding real-time monitoring, tracking, and comparison of all rows in the memory, and thus reducing the monitoring burden of the memory. In addition, since the row address with the maximum activation count in the page table is output as the candidate row address, the adjacent rows thereof can be periodically refreshed, thereby reducing the frequency of pause of memory operation and improving the operating efficiency of the memory.

In some embodiments, the first preset condition includes: an available entry not storing a row address is present in the page table, the currently activated row address is the same as the row address stored in the page table, or the activation count of the currently activated row address is greater than a minimum value among the activation counts of the plurality of row addresses stored in the page table.

Specifically, as shown in FIG. 2, the status register 211 may store one bit of data. When the bit of data is at an active level (e.g., a high level), it indicates that the row address register 212 and the activation count register 213 of the row store information. When the bit of data is at an inactive level (e.g., a low level), it indicates that the row address register and the activation count register 213 of the row do not store information. If the status register 211 indicates that at least one row in the page table is not occupied (that is, the row address register and the activation count register 213 in at least one row do not store information), there is still an available entry not storing a row address in the page table. In this case, the first preset condition is met, and the currently activated row address and the activation count thereof may be stored in the page table 210.

Alternatively, if the first comparison circuit 220 finds through comparison that the currently activated row address is the same as a row address stored in the page table, since the activation count carried by the currently activated row address is updated, the activation count carried by the currently activated row address may be directly updated into the page table 210, to replace the original activation count in the activation count register 213 corresponding to the row address.

Alternatively, if the first comparison circuit 220 finds through comparison that the activation count of the currently activated row address is greater than the minimum value among the activation counts of a plurality of row addresses stored in the page table, the first comparison circuit may directly update the currently activated row address and the activation count carried by the currently activated row address into the page table 210, to replace the row address and the activation count of the row address that corresponds to the minimum value among the activation counts of the plurality of row addresses stored in the page table. In this case, data stored in the row address register 212 and data stored in the activation count register 213 are both updated.

In this way, the currently activated row address and the activation count thereof can be temporarily stored in the page table, and the activation count can be updated in real time. In addition, through the comparison of the minimum value of the activation count, the row addresses with higher activation counts are retained. This simply and easily enables monitoring and comparison of all row addresses and the activation counts thereof, and avoids the heavy workload of one-by-one monitoring and comparison of the activation counts for 64K rows.

In some embodiments, the refresh control circuit is further configured to generate an Alert Back-off (Alert Back-off, ABO) signal when a second preset condition is met. The Alert Back-off signal is a flag signal in a memory for pausing a read/write operation and performing a refresh operation. Once the Alert Back-off signal is triggered, the memory stops all other operations (including a read operation, a write operation, an activation operation, etc.) and only performs the refresh operation. The Alert Back-off signal is triggered by the memory and received by a memory controller. After receiving the Alert Back-off signal, the memory controller immediately controls the memory to pause the read/write operation for refresh.

In some embodiments, the second preset condition may be that the minimum value among the activation counts of all row addresses in the page table 210 is greater than a preset threshold. Since the first comparison circuit 220 compares the currently activated row address and the activation count thereof with the row address and the activation count thereof in the page table, the first comparison circuit 220 may be employed to compare the minimum value among the activation counts of all row addresses in the page table 210 with the preset threshold. If the minimum value among the activation counts of all row addresses in the page table 210 is greater than the preset threshold, an Alert Back-off signal is transmitted.

In some other embodiments, the second preset condition may be that the activation counts of three row addresses in the page table 210 are greater than the preset threshold. That is, three pieces of data in the activation count register 213 are greater than the preset threshold. The present disclosure is not limited thereto, and the second preset condition may also be that the activation counts of two/four row addresses in the page table 210 are greater than the preset threshold, or may be other situations.

The specific value setting of the preset threshold may be determined individually by any one of multiple factors, such as a process yield, an operating frequency, and a refresh frequency, or jointly by a combination thereof. In some embodiments, the preset threshold may be set to, for example, 3000.

In this way, by setting a triggering condition for the Alert Back-off signal through the second preset condition, when a row or some rows exhibit excessive activation counts, the memory can be refreshed in time to mitigate the vulnerability and correct the fault. In addition, by configuring the Alert Back-off signal to be triggered when the minimum value among the activation counts of all row addresses in the page table is greater than the preset threshold, the first comparison circuit can be reused, thereby saving circuit processing logic and reducing chip area.

In some embodiments, the page table 210 is configured to store, in a first time period, a row address output by the first comparison circuit 220 and the activation count thereof. The page table 210 is further configured to store, in a second time period, a row address output by a third comparison circuit (not shown in the figure), and perform an operation of increment by 1 on the count value corresponding to the row address stored in the page table.

Specifically, the first comparison circuit 220 receives the currently activated row address and the activation count thereof. The third comparison circuit (not shown in the figure) receives the randomly sampled row address received by a random sampling circuit, and discovers and selects the candidate row address for Row Hammer by matching the sampled address with the address stored in the page table and comparing the count value corresponding to the row address stored in the page table with the count value of the randomly sampled row address obtained by counting activations. The comparison mode of the third comparison circuit is different from that of the first comparison circuit 220. Correspondingly, in the first time period, the page table 210 and the first comparison circuit 220 performs selection and operation on the row address and the activation count in the PRAC mode, while in the second time period, the page table 210 and the third comparison circuit performs selection and operation on the randomly sampled row address and the activation count thereof in the DLUT (Dynamic Look-up Table, dynamic look-up table) mode. In this way, the page table can be reused in different time periods and in implementing different functions.

In the DLUT mode, the count value of a frequently accessed row is identified by using a dynamic lookup table method, and the adjacent rows of the frequently accessed candidate row address are refreshed. In the DLUT mode, since the activation count is not stored in the row, the activation count register 213 in the page table cannot directly obtain the activation count. Therefore, the activation count register 213 in the page table correspondingly stores the count value of the sampled row, and each time the sampled row address is the same as a row address stored in the page table, the count value of the sampled row address is incremented by 1. When the sampled row address does not match the row address stored in the page table, the sampled row address is placed in an available entry (if any) in the page table, and meanwhile, the counter is set to 1. In this way, the number of accesses is counted. In this case, the function of the activation count register 213 as a counter may be implemented by using a counter.

Since the PRAC mode and the DLUT mode are not used in the same time period, the page table 210 can be reused across the two modes, thereby saving memory area consumed by the large page table. In addition, each time the memory restarts or the mode switches, the page table 210 is reset, thereby preventing data conflicts.

In some embodiments, the first comparison circuit and the third comparison circuit may each be further connected to the page table 210 and a power supply through a switch. In the PRAC mode, the connection between the third comparison circuit and the page table 210, as well as the connection between the third comparison circuit and the power supply may be disabled; in the DLUT mode, the connection between the first comparison circuit and the page table 210, as well as the connection between the third comparison circuit and the power supply may be disabled, thereby reducing power consumption. In some other embodiments, since the PRAC mode and the DLUT mode are not simultaneously enabled, the switch may also not be provided. When the PRAC function is not enabled, the DLUT mode may be employed to prevent a Row Hammer attack, thereby ensuring the integrity of circuit data.

In some embodiments, the refresh control circuit 20 is configured to receive a refresh command periodically (i.e., at fixed intervals or variable intervals), refresh, based on the refresh command, one or more rows adjacent to the candidate row address, and remove the candidate row address from the page table.

The refresh command may include a Row Hammer Refresh (Row Hammer Refresh, RHR) command and a Refresh Management (Refresh Management, RFM) command that are issued by the system. The refresh control circuit 20 may further include a refresh circuit (not shown in the figure). The refresh circuit is connected to the second comparison circuit 230. The refresh circuit receives the candidate row address and determines, based on the candidate row address, one or more row addresses adjacent to the candidate row address. The refresh circuit refreshes the one or more row addresses adjacent to the candidate row address, and removes the candidate row address from the page table 210 after the refreshing. After the removal, an available entry is reserved in the page table 210; the available entry may be indicated by the status register 211.

In this way, by monitoring the row addresses with the maximum activation counts and periodically performing Row Hammer refresh protection on these row addresses, the possibility of data flips caused by accumulated activation counts can be reduced, and preemptive predictions are enabled. As a result, the triggering of the Alert Back-off (ABO) mechanism can be reduced, thereby effectively improving the system performance, and preventing the efficiency from being lowered due to pause of system operation caused by triggering of the Alert Back-off (ABO) mechanism.

As shown in FIG. 3, the embodiments of the present application further provide a memory 1. The memory 1 includes the refresh control circuit 20 according to any one of the foregoing embodiments and a bank 10. The bank 10 includes a plurality of rows, and the plurality of rows store memory data and activation counts.

The row is a row formed by a plurality of memory cells, the memory data is information that can be normally stored in each row, and the activation count is the number of times the memory row is activated within one counting period (or another period, such as a refresh period). In some embodiments, at each activation, the row address of the row and the activation count of the row are input into the refresh control circuit 20 for refresh control operation, and the activation count of the row is reset (initialized) after the refreshing of the row. In some embodiments, not at each activation, the row address of the currently activated row and the activation count of the row are input into the refresh control circuit 20. Activated rows with certain activation counts may be selected based on a certain rule, and the row addresses of these activated rows and the activation counts thereof are input into the refresh control circuit 20 for refresh control operation.

In some embodiments, the memory 1 includes a plurality of banks 10 and a plurality of refresh control circuits 20, and each bank is correspondingly provided with one refresh control circuit.

In some embodiments, the memory 1 further includes an Alert Back-off signal transmission circuit (not shown in the figure). The Alert Back-off signal transmission circuit receives the Alert Back-off signal, and adjusts the Alert Back-off signal into a waveform required by the memory controller, e.g., converting an active-high signal into an active-low signal, or performing shaping on the waveform, or adjusting a pulse of one level cycle into a two-cycle pulse, and performs path driving on the Alert Back-off signal. The Alert Back-off signal transmission circuit transmits the Alert Back-off signal to a memory controller (Memory Controller); the memory controller receives the Alert Back-off (ABO) signal, and transmits, based on the Alert Back-off signal, a Row Hammer Refresh (RHR) command or a Refresh Management (RFM) command to the memory, so as to instruct the memory to refresh. Correspondingly, a mode register (Mode Register, MR) may be newly added to the memory, for example, MR70. When the mode register is set to a specific value, for example, MR70:OP[1] = 1B, the PRAC mode is enabled.

In this way, through the above design, it is possible to avoid monitoring and tracking all rows of the memory in real time, thereby reducing the monitoring burden of the memory. In addition, since the adjacent rows can be periodically refreshed, the frequency of pause of memory operation can be reduced, thereby improving the operating efficiency of the memory.

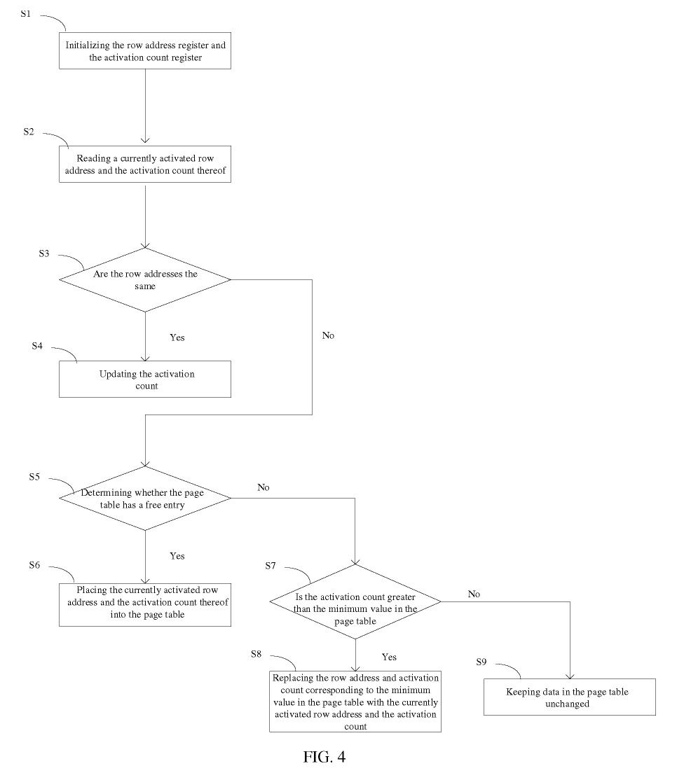

FIG. 4 is a flowchart of a refresh control method according to an embodiment of the present disclosure. The refresh control method may be implemented by using the refresh control circuit and the memory according to any one of the above embodiments. As shown in FIG. 4, the refresh control method includes:

determining whether a currently activated row address is the same as a row address stored in a page table (i.e., step S3 in FIG. 4);

if the currently activated row address is the same as the row address stored in the page table, updating an activation count corresponding to the row address in the page table to an activation count carried by the currently activated row address (i.e., step S4 in FIG. 4);

if the currently activated row address is not the same as the row address stored in the page table, comparing an activation count carried by the currently activated row address with a minimum value of an activation count in the page table, and determining whether the activation count carried by the currently activated row address is greater than the minimum value of the activation count in the page table (i.e., step S7 in FIG. 4);

if the activation count carried by the currently activated row address is greater than the minimum value of the activation count in the page table, replacing a row address corresponding to the minimum value of the activation count in the page table and the activation count thereof with the currently activated row address and the activation count thereof (i.e., step S8 in FIG. 4); and

if the activation count carried by the currently activated row address is less than the minimum value of the activation count in the page table, keeping data in the page table unchanged (i.e., step S9 in FIG. 4).

In step S3, if a plurality of row addresses are stored in the page table, it is determined whether the currently activated row address is the same as any one of the plurality of row addresses stored in the page table. If the currently activated row address is the same as any one of the plurality of row addresses stored in the page table, the condition for updating the activation count is met, and the activation count of the same row address in the page table is replaced with the activation count of the currently activated row address. Step S3 may be implemented by the first comparison circuit 220 in FIG. 2.

In step S4, the activation count carried by the currently activated row address refers to the activation count corresponding to the currently activated row address. The activation count may be stored by the currently activated row and read from the row during activation, or may be stored or calculated in other ways. The activation count updated in step S4 may be the updated activation count in the activation count register 213 in FIG. 2.

Step S7 may be implemented by the first comparison circuit 220 in FIG. 2, the minimum value of the activation count in the page table may be found by the first comparison circuit 220, and the comparison between the activation count carried by the currently activated row address and the minimum value of the activation count in the page table may also be completed by the first comparison circuit 220.

In step S9, data in the page table is kept unchanged, and the currently activated row address and the activation count thereof may be discarded outside the page table.

In this way, by storing the activated row address and the activation count thereof in the page table, and comparing the currently activated row address and the activation count thereof with the row address and the activation count thereof stored in the page table each time, the row addresses with higher activation counts can be selected, thereby avoiding real-time monitoring and tracking of all rows in the memory, and thus reducing the monitoring burden of the memory.

In some embodiments, before step S3, the following steps are further provided: initializing a row address register and an activation count register in a page table (i.e., step S1 in FIG. 4), where the row address register and the activation count register may be the row address register 212 and the activation count register 213 in FIG. 2; and

reading a currently activated row address and the activation count thereof (i.e., step S2 in FIG. 4), and transmitting the row address of the currently activated row and the activation count thereof to the first comparison circuit 220 for comparison operation.

Between step S4 and step S7, the following steps are further provided:

if the currently activated row address is different from the row address stored in the page table, determining whether an available entry is present in the page table (i.e., step S5 in FIG. 4);

if there remains an available entry in the page table, the currently activated row address and the activation count thereof are placed in the available entry in the page table (i.e., step S6 in FIG. 4); and

if no available entry is present in the page table, comparison and determination in step S7 are performed.

In some embodiments, the refresh control method further includes:

comparing the minimum value of the activation count in the page table with a preset threshold, and generating an Alert Back-off (ABO) signal if the minimum value of the activation count in the page table is greater than the preset threshold, or not generating an Alert Back-off signal if the minimum value of the activation count in the page table is not greater than the preset threshold,

where the Alert Back-off signal is a flag signal in a memory for pausing a read/write operation and performing a refresh operation.

Once the Alert Back-off signal is triggered, the memory stops all other operations (including a read operation, a write operation, an activation operation, etc.) and only performs the refresh operation. The Alert Back-off signal is triggered by the memory and received by the memory controller. After receiving the Alert Back-off signal, the memory controller immediately controls the memory to pause the read/write operation for refresh.

The specific value setting of the preset threshold may be determined individually by any one of multiple factors, such as a process yield, an operating frequency, and a refresh frequency, or jointly by a combination thereof. In some embodiments, the preset threshold may be set to, for example, 3000.

In some other embodiments, it may also be configured such that an Alert Back-off signal is generated when a predefined number of activation counts (e.g., three or four) in the page table is greater than the preset threshold. This lowers the triggering condition for the Alert Back-off signal and improves data stability.

In this way, by setting a triggering condition for the Alert Back-off signal, when a row or some rows exhibit excessive activation counts, the memory can be refreshed in time to mitigate the vulnerability and correct the fault. In addition, by configuring the Alert Back-off signal to be triggered when the minimum value among the activation counts of all row addresses in the page table is greater than the preset threshold, the circuit processing logic can be simplified, thereby reducing chip area.

In some embodiments, the refresh control method further includes: finding, through comparison, a row address with the maximum activation count in the page table, and refreshing one or more rows adjacent to the row address with the maximum activation count in the page table. After the refreshing, the row address with the maximum activation count may be removed from the page table. The comparison may be implemented by the second comparison circuit 230.

Since the row address with the maximum activation count in the page table is found through comparison, and the rows adjacent to the row address with the maximum activation count in the page table are periodically refreshed, the protection against Row Hammer can be performed on the row with a higher activation count in advance, thereby reducing the frequency of pause of memory operation and improving the operating efficiency of the memory.

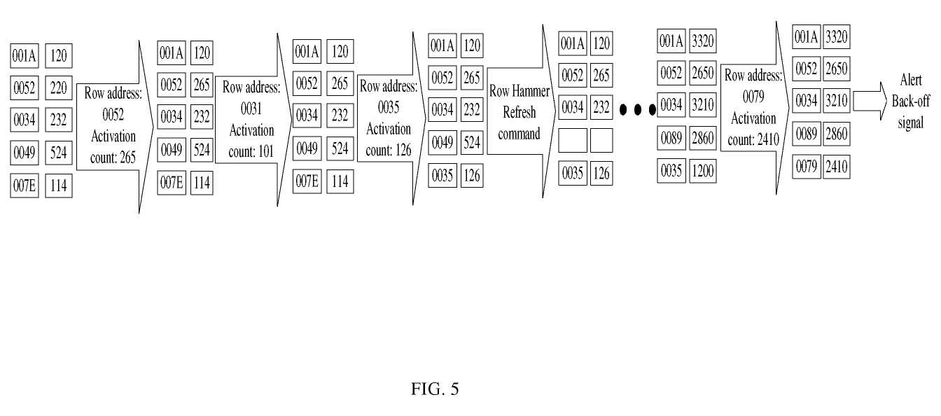

FIG. 5 is a schematic diagram of a dynamic change of data in a page table according to an embodiment of the present application. In FIG. 5, the case where the row address register includes five rows, the second preset condition is that the minimum value among all activation counts in the page table is greater than a preset threshold, and the preset threshold is 2400 is used as an example. In FIG. 5, the row address is represented by a hexadecimal number.

After a period of operation, the five row addresses stored in the page table are 001A (corresponding to an activation count of 120), 0052 (corresponding to an activation count of 220), 0034 (corresponding to an activation count of 232), 0049 (corresponding to an activation count of 524), and 007E (corresponding to an activation count of 114), respectively.

Subsequently, the memory is activated; the activated row address is 0052, and the corresponding activation count thereof is 265. Based on the process shown in FIG. 4, according to step S3, it is determined that the currently activated row address is the same as the row address stored in the second row in the page table. Therefore, the activation count of the second row address is updated to the activation count 265 carried by the currently activated row address.

Subsequently, the memory is activated; the activated row address is 0031, and the corresponding activation count thereof is 101. Based on the process shown in FIG. 4, according to step S3, it is determined that the currently activated row address is different from the row addresses of all rows in the page table; according to step S5, no available entry is present in the page table; and according to step S7, the activation count of the currently activated row address is less than the minimum value 114 among the activation counts in the page table. Therefore, the data in the page table is kept unchanged.

Subsequently, the memory is activated; the activated row address is 0035, and the corresponding activation count thereof is 126. Based on the process shown in FIG. 4, after steps S3, S5, and S7, since the activation count of the currently activated row address is greater than the minimum value 114 among the activation counts in the page table, step S8 is performed to replace, with the currently activated row address and the activation count thereof, the row address and the activation count thereof that correspond to the minimum value in the page table. In this case, the fifth row of the page table is replaced with 0035, and the corresponding activation count thereof is 126.

Subsequently, the memory receives the Row Hammer Refresh (RHR) command; then, based on the comparison result, obtained by the second comparison circuit 230, that the maximum value among the activation counts is 524, the row address of the fourth row in the page table is output for the Row Hammer Refresh Protection operation, and the row address of the fourth row and the activation count thereof in the page table are cleared.

After a plurality of operation, the five row addresses stored in the page table are 001A (corresponding to an activation count of 3320), 0052 (corresponding to an activation count of 2650), 0034 (corresponding to an activation count of 3210), 0089 (corresponding to an activation count of 2860), and 0035 (corresponding to an activation count of 1200), respectively. Subsequently, the memory is activated; the activated row address is 0079, and the corresponding activation count thereof is 2410. After the row address enters the page table through step S8, the minimum value among the activation counts of the row addresses in the page table is greater than the preset threshold 2400, and in this case, the refresh control circuit generates an Alert Back-off signal to instruct the controller to control the memory to pause operations for refresh.

Those of ordinary skill in the art can understand that the above implementations are specific embodiments of practicing the present application, while in practical applications, various changes can be made to the implementations in form and detail without departing from the spirit and scope of the present application. Any person skilled in the art can make respective changes and modifications without departing from the spirit and scope of the present application, and the protection scope of the present application is defined by the appended claims.

What is claimed is:

1. A refresh control circuit, comprising a page table, a first comparison circuit, and a second comparison circuit, wherein
the page table is configured to store a plurality of row addresses and activation counts of the plurality of row addresses;
the first comparison circuit is connected to the page table, and is configured to receive a currently activated row address and an activation count thereof, compare the currently activated row address and the activation count thereof with the plurality of row addresses and the activation counts thereof stored in the page table, and store, when a first preset condition is met, the currently activated row address and the activation count thereof into the page table; and
the second comparison circuit is connected to the page table, and is configured to compare the activation counts of the plurality of row addresses in the page table, and output a row address with a maximum activation count as a candidate row address.

2. The refresh control circuit according to claim 1, wherein the refresh control circuit is configured to generate an Alert Back-off signal when a second preset condition is met, wherein the Alert Back-off signal is a flag signal in a memory for pausing a read/write operation and performing a refresh operation.

3. The refresh control circuit according to claim 2, wherein the second preset condition is that a minimum value among activation counts of all row addresses in the page table is greater than a preset threshold.

4. The refresh control circuit according to claim 1, wherein the page table is configured to store, in a first time period, a row address output by the first comparison circuit and an activation count thereof; and the page table is further configured to store, in a second time period, a row address output by a third comparison circuit, and perform an operation of increment by 1 on a count value corresponding to the row address stored in the page table.

5. The refresh control circuit according to claim 1, wherein the refresh control circuit is configured to periodically receive a refresh command, refresh, based on the refresh command, one or more rows adjacent to the candidate row address, and remove the candidate row address from the page table.

6. The refresh control circuit according to claim 1, wherein the first preset condition comprises: an available entry not storing a row address is present in the page table, the currently activated row address is the same as the row address stored in the page table, or the activation count of the currently activated row address is greater than a minimum value among the activation counts of the plurality of row addresses stored in the page table.

7. A memory, comprising the refresh control circuit according to claim 1 and a bank, wherein the bank comprises a plurality of rows, and the plurality of rows store memory data and activation counts.

8. A refresh control method, comprising:
determining whether a currently activated row address is the same as a row address stored in a page table;
if the currently activated row address is the same as the row address stored in the page table, updating an activation count corresponding to the row address in the page table to an activation count carried by the currently activated row address;
if the currently activated row address is not the same as the row address stored in the page table, comparing an activation count carried by the currently activated row address with a minimum value of an activation count in the page table, and determining whether the activation count carried by the currently activated row address is greater than the minimum value of the activation count in the page table;
if the activation count carried by the currently activated row address is greater than the minimum value of the activation count in the page table, replacing a row address corresponding to the minimum value of the activation count in the page table and the activation count thereof with the currently activated row address and the activation count thereof; and
if the activation count carried by the currently activated row address is less than the minimum value of the activation count in the page table, keeping data in the page table unchanged.

9. The refresh control method according to claim 8, further comprising:
comparing the minimum value of the activation count in the page table with a preset threshold, and generating an Alert Back-off signal if the minimum value of the activation count in the page table is greater than the preset threshold,
wherein the Alert Back-off signal is a flag signal in a memory for pausing a read/write operation and performing a refresh operation.

10. The refresh control method according to claim 8, further comprising:
refreshing one or more rows adjacent to a row address with a maximum activation count in the page table.
